(19) United States
(12) Patent Application Publication
(10) Pub. No.: US 2014/0322654 A1
(43) Pub. Date: Oct. 30, 2014

(54) LITHOGRAPHY APPARATUS, AND METHOD FOR MANUFACTURING ARTICLE

(71) Applicant: CANON KABUSHIKI KAISHA, Tokyo (JP)

(72) Inventors: Koichi Sentoku, Kawachi-gun (JP); Hideki Ina, Tokyo (JP)

(73) Assignee: CANON KABUSHIKI KAISHA, Tokyo (JP)

(21) Appl. No.: 14/263,725

(22) Filed: Apr. 28, 2014

(30) Foreign Application Priority Data
Apr. 30, 2013 (JP) 2013-096009

(51) Int. Cl. G03F 7/20; H01J 37/317

(52) U.S. Cl. CPC G03F 7/2037; H01J 37/3174; H01J 2237/202
USPC 430/296; 250/453.11

(57) ABSTRACT

A lithography apparatus for substrate patterning, includes a substrate stage having a reference mark, an optical system irradiating the substrate with the charged particle beam, a first measurement device measuring a position of an alignment mark formed on the substrate, a second measurement device having an optical axis apart from an axis of the optical system by a distance shorter than that of the first measurement device, and measuring a position of the reference mark, a processor obtaining a base line of the first measurement device based on positions of the reference mark respectively measured by the first and second measurement device and a base line of the second measurement device, the position of the reference mark being measured by the second measurement device based on an optical signal obtained via the reference mark with the stage moved.

### BACKGROUND OF THE INVENTION

1. Field of the Invention

The present invention relates to a lithography apparatus, and a method for manufacturing an article.

2. Description of the Related Art

As a lithography apparatus for manufacturing a semiconductor device or the like, there has been an exposure apparatus for projecting a reticle pattern on a substrate (wafer) or a drawing apparatus for drawing on a substrate with a charged particle beam. In the lithography apparatus, an alignment mark formed on the substrate is measured for achieving the necessary overlapping accuracy.

In the conventional exposure apparatus, for example, the alignment mark is measured using an off-axis scope OAS disposed apart from an optical axis AX_{PL} of a projection optical system PL as illustrated in FIG. 12. The distance (or displacement vector) on the substrate between the optical axis AX_{OAS} of the scope OAS and the optical axis AX_{PL} of the projection optical system PL is called a base line BL. The base line BL is measured at an appropriate time, and based on the measurement result, the position of the substrate is adjusted (aligned) at the necessary accuracy.

In the measurement of the base line BL, the position of the optical axis AX_{PL} of the projection optical system PL is detected via a reticle and the projection optical system, i.e., by a detection system DS of through the reticle (TTR) and through the lens (TTL). Specifically, the detection system DS detects images of a reference mark RM1 and a reference mark RM2 on a reticle R and an image of a reference mark M1 on a substrate stage ST formed via the projection optical system PL. Based on the relative positional relation among those images, the position of the optical axis AX_{PL} of the projection optical system PL can be obtained (measured). The detection system DS may desirably employ light (exposure light) used for exposing the substrate via the reticle, for example, because the aberration in the projection optical system PL is smaller.

The base line BL is measured by, first, detecting the image of the reference mark M0 on the stage ST with the scope OAS to obtain the position of the optical axis AX_{OAS} of the scope OAS as the coordinate of the stage ST. Next, the reference mark M1 and the stage ST are moved to below the projection optical system PL, and the position of the optical axis AX_{PL} of the projection optical system PL is obtained as the coordinate of the stage ST by the detection system DS as described above. Thus, the base line BL is obtained from both coordinates.

A charged particle beam drawing apparatus, which serves as a maskless lithography apparatus that does not require a reticle (also called mask), can have the aforementioned scope OAS but cannot have the detection system DS using the reticle. A technique to measure the base line in such a drawing apparatus is discussed in Japanese Patent Application Laid-Open No. 2000-133566. Japanese Patent Application Laid-Open No. 2000-133566 discusses a technique for measuring the base line with a detection system for detecting the charged particle beam instead of the aforementioned detection system DS.

Moreover, a lithography apparatus including a mark position detection system is discussed in WO2012/158025, in which an object optical element (lens or mirror, for example) is disposed below a projection system for projecting an electron beam to a substrate (disposed at a support part of the projection system).

In the measurement of the base line, however, the technique according to Japanese Patent Application Laid-Open No. 2000-133566 may be disadvantageous in terms of accuracy required for the future lithography (for example, the lithography for manufacturing a semiconductor device with a half pitch of 16 nm or less). One reason of this is the low S/N ratio of a signal obtained in the measurement in which the charged particle beam is used. When the measurement is conducted more frequently for achieving the required measurement accuracy, it takes long time and this is not advantageous in point of throughput. Further, WO2012/158025 does not discuss the measurement of the base line of the mark position detection system.

### SUMMARY OF THE INVENTION

The present invention is directed to, for example, a lithography apparatus that is advantageous in measurement of the base line.

According to an aspect of the present invention, a lithography apparatus configured to form a pattern on a substrate with a charged particle beam, includes a stage having a reference mark and configured to hold the substrate and be moveable, an optical system configured to irradiate the substrate with the charged particle beam, a first measurement device having an optical axis apart from an axis of the optical system by a first distance, and configured to measure a position of an alignment mark formed on the substrate, a second measurement device having an optical axis apart from the axis of the optical system by a second distance shorter than the first distance, and configured to measure a position of the reference mark, and a processor configured to obtain a base line of the first measurement device based on positions of the reference mark respectively measured by the first measurement device and the second measurement device and a base line of the second measurement device, wherein the position of the reference mark is measured by the second measurement device based on an optical signal obtained via the reference mark with the stage moved.

Further features of the present invention will become apparent from the following description of exemplary embodiments with reference to the attached drawings.

### BRIEF DESCRIPTION OF THE DRAWINGS

FIG. 1 is a diagram illustrating a structure example of a lithography apparatus.

FIG. 2 is a flowchart illustrating an example of a flow of measuring a base line.

FIG. 3 is a diagram illustrating an operation performed in step S1 in FIG. 2.

FIG. 4 is a diagram illustrating an output signal of an electron detector.

FIG. 5 is a diagram illustrating an operation performed in step S2 in FIG. 2.

FIG. 6 is a diagram for describing step S3 in FIG. 2.

FIGS. 7A and 7B are top views each illustrating a structure example of a stage (reference mark) according to a first exemplary embodiment.

FIGS. 8A and 8B are diagrams each illustrating an outline of measurement of a reference mark.

FIGS. 9A, 9B, 9C, 9D, 9E, and 9F are diagrams illustrating details of the measurement of the reference marks.

FIGS. 10A, 10B, 10C, 10D, 10E, and 10F are diagrams illustrating comparative examples of the measurement of the reference marks.

FIGS. 11A and 11B are top views each illustrating a stage (reference mark) according to a second exemplary embodiment.

FIG. 12 is a diagram illustrating a structure example of a conventional exposure apparatus.

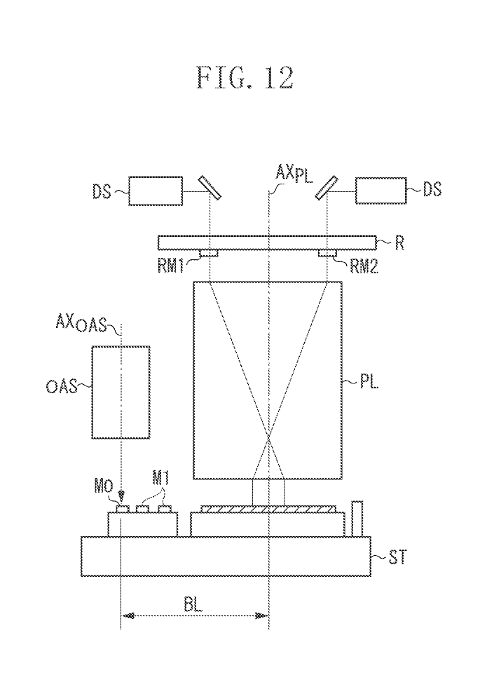

### DESCRIPTION OF THE EMBODIMENTS

Various exemplary embodiments, features, and aspects of the invention will be described in detail below with reference to the drawings. Throughout the drawings illustrating the exemplary embodiments, in principle, the same components are denoted by the same reference symbols (unless otherwise stated) and the description thereof is not repeated.

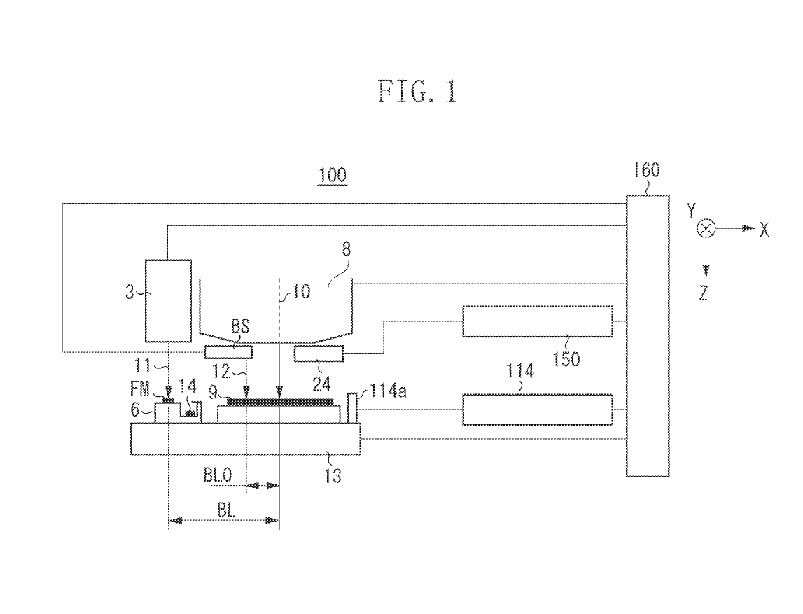

FIG. 1 is a diagram illustrating a structure example of a lithography apparatus 100 as an aspect of an exemplary embodiment of the present invention. The lithography apparatus 100 is a lithography apparatus that forms (draws) a pattern on a substrate with one or a plurality of charged particle beams (electron beams). Although description is made of the case in which the electron beam is employed as the charged particle beam here, the present invention is not limited thereto.

The lithography apparatus 100 includes a stage 13 that can move while holding a substrate 9, an electron optical system (charged particle optical system) 8, a first measurement unit 3, a second measurement unit BS, an acquisition unit 150, and a control unit (also referred to as a process unit) 160.

The stage 13 is provided with a reference mark table 6 having a reference mark FM formed thereon as illustrated in FIG. 1. The reference mark FM is a mark used in the measurement of a base line. The position of the stage 13 is measured by a position measuring instrument 114 including a mirror 114a provided on the stage 13. The position measuring instrument 114 may include a laser interferometer. However, the method and arrangement of the position measuring instrument 114 are not limited to those above. The position measuring instrument 114 may include, for example, an encoder including a scale.

The electron optical system 8 may include at least one of, for example, an electron gun (electron source), a collimator lens, an aperture array, an electron (charged particle) lens, a blanca array, a stopping aperture array, and a deflector (deflecting device). The electron optical system 8 is housed in a case (lens barrel) and irradiates the substrate 9 with an electron beam from an electron gun.

The first measurement unit 3 includes an off-axis scope having an optical axis at a position apart from an optical axis (axis) 10 of the electron optical system 8. In the present exemplary embodiment, the first measurement unit 3 has an optical axis 11 that is apart from the optical axis 10 of the electron optical system 8 by a first distance (BL), and measures the position of the alignment mark formed on the substrate 9 as the coordinate of the stage 13. The first measurement unit 3 measures the position of the reference mark FM on the stage 13 as the coordinate of the stage 13.

The second measurement unit BS has at least a part thereof (including an object optical element thereof) disposed below the electron optical system 8, for example, below the case housing the electron optical system 8. The object optical element may include an object lens or an object mirror, for example. The second measurement unit BS has an optical axis 12 at a position apart from the optical axis AX1 of the electron optical system 8 by a second distance (BL0) shorter than the first distance, and measures the position of the reference mark FM on the stage as the coordinate of the stage 13. The second measurement unit BS is a base line measurement scope used for obtaining the distance (displacement vector) between the optical axis AX1 of the electron optical system 8 and the optical axis 11 of the first measurement unit 3, i.e., obtaining the base line of the first measurement unit 3. The base line generally expressed in a vector quantity but for simplifying the description, the base line may be expressed in a scalar quantity or a particular component of the vector quantity.

In the present exemplary embodiment, the first measurement unit 3 and the second measurement unit BS include an image sensor for capturing an image of the alignment mark or the reference mark FM formed on the substrate 9, and measure the position of the mark by processing (image-processing) an image signal obtained from the image sensor. The method for measuring the position of the reference mark FM by the first measurement unit 3 and the second measurement unit BS, however, is not limited thereto and may be another applicable method known to a person skilled in the art. For example, the first measurement unit 3 and the second measurement unit BS may measure the position of the mark based on a measurement signal of light (optical signal) from the mark obtained by scanning (moving) the substrate stage 13 instead of detecting the image of the still mark.

The acquisition unit 150 acquires the position of the optical axis 10 of the electron optical system 8. In the present exemplary embodiment, the acquisition unit 150 is embodied as the measurement unit that actually measures the position of the optical axis AX1 of the electron optical system 8 as described below. However, the acquisition unit 150 may alternatively be embodied as a storage unit that stores the position of the optical axis 10 of the electron optical system 8 input by a user. The user may, for example, input an optical design value of the electron optical system 8. In this case, the acquisition unit 150 is embodied as a calculator (simulator) that obtains the position of the optical axis 10 of the electron optical system 8 based on the optical design value of the electron optical system 8.

The control unit 160 (process unit) includes a processor such as a central processing unit (CPU), a digital signal processor (DSP), or a field programmable gate array (FPGA), or a process device, a memory. However, the control unit 160 is not limited thereto as long as the control unit 160 is configured to control the operation of each component of the lithography apparatus 100. Specifically, the control unit 160 controls the process of forming (drawing) a pattern on the substrate 9 with the electron beam. The control unit 160 moreover controls the process for measuring the base line of the first measurement unit 3. For example, the control unit 160 obtains the base line of the first measurement unit 3 based on the position of the reference mark FM and the base line of the second measurement unit BS measured by the first measurement unit 3 and the second measurement unit BS through the movement of the stage 13. Here, the base line of the second measurement unit BS is the distance (displacement vector) between the optical axis 10 of the electron optical system 8 and the optical axis 12 of the second measurement unit BS.

The process for measuring the base line of the lithography apparatus 100 is described. Here, as illustrated in FIG. 1, the distance (displacement vector) between the optical axis 10 of the electron optical system 8 and the optical axis 12 of the second measurement unit BS, i.e., the base line of the second measurement unit BS is defined as BL0. Moreover, the distance (displacement vector) between the optical axis 10 of the electron optical system 8 and the optical axis 11 of the first measurement unit 3, i.e., the base line of the first measurement unit 3 is defined as BL. Further, it is assumed that the first measurement unit 3 measures the position by processing the image obtained by capturing the image of the still mark and that the second measurement unit BS measures the position based on the measurement signal obtained by receiving reflection light (optical signal) from the moving mark.

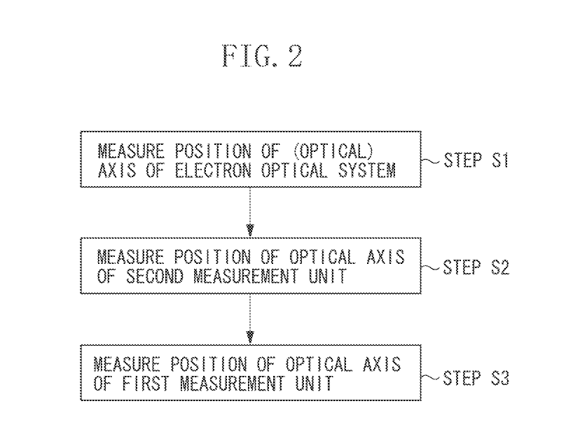

FIG. 2 is a diagram (flowchart) illustrating a flow of the measurement of the base line. The operation of each step of the lithography apparatus in FIG. 2 is executed under the control of the control unit 160. In FIG. 2, step S2 and step S3 correspond to the general process for measuring the base line, and step S1 and step S2 correspond to the process that is performed less frequently. The steps are hereinbelow described in order.

### <Step S1: Measurement of Position of Optical Axis (Axis) of Electron Optical System 8>

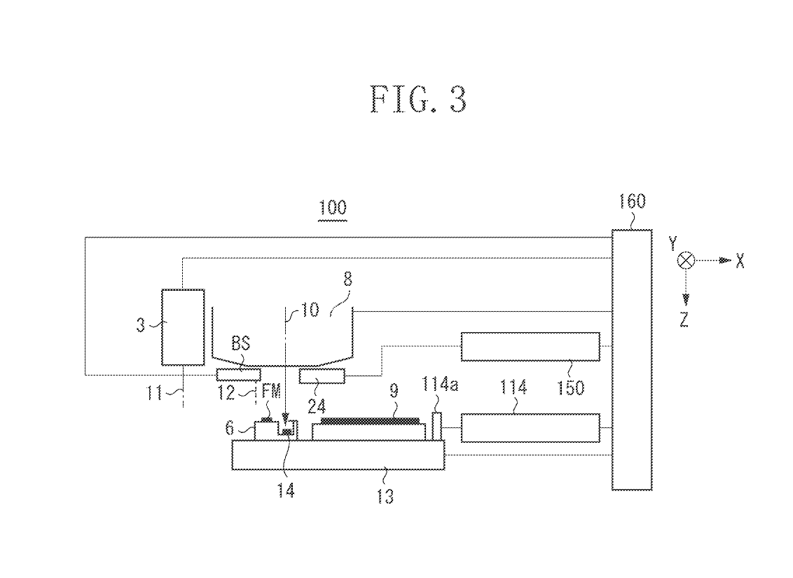

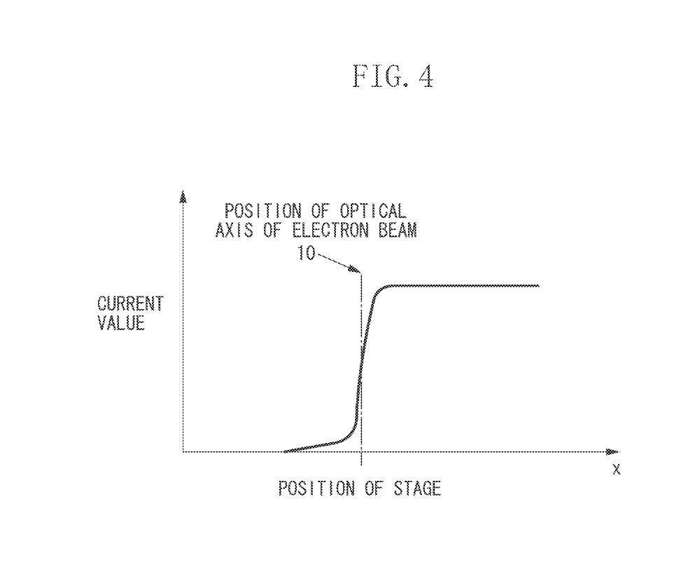

The operation of step S1 is described with reference to FIG. 3. FIG. 3 illustrates the state of measuring the position of the optical axis 10 of the electron optical system 8. The electron beam emitted along the axis of the electron optical system 8 enters an electron beam detector 14 including a Faraday cup provided for the reference mark table 6. FIG. 4 illustrates an output signal of the electron beam detector 14 when the stage 13 is scanned (moved) in the +X direction. The plane of the electron beam detector 14 that receives the electron beam is provided with a knife edge. Therefore, the movement of the stage 13 relative to the electron beam changes the amount (current value) of the electron beam entering the Faraday cup, so that the output of the electron beam detector 14 as illustrated in FIG. 4 is obtained. The position (L1) of the optical axis 10 of the electron optical system 8 may be determined by the position at which the value (differential value) obtained by differentiating the output curve of FIG. 4 with the position of the stage is the maximum.

The method for measuring the position of the optical axis 10 of the electron optical system is not limited to this method. For example, the reference mark FM on the moving reference mark table 6 may be irradiated with the electron beam and the electron (secondary electron or dispersed electron) coming from the reference mark FM may be detected with another electron beam detector 24 (scanning electron microscope (SEM) mode). In general, the measurement unit (third measurement unit) including the electron beam detector 14 or 24 with the Faraday cup has a low S/N ratio of the detection signal of the electron beam, therefore, the measurement needs to be conducted multiple times for achieving the necessary measurement accuracy. Step S1, however, may be performed less frequently, e.g., step S1 may be conducted when the lithography apparatus is not in operation. Therefore, the throughput is hardly affected.

### <Step S2: Measurement of Position of Optical Axis of Second Measurement Unit BS>

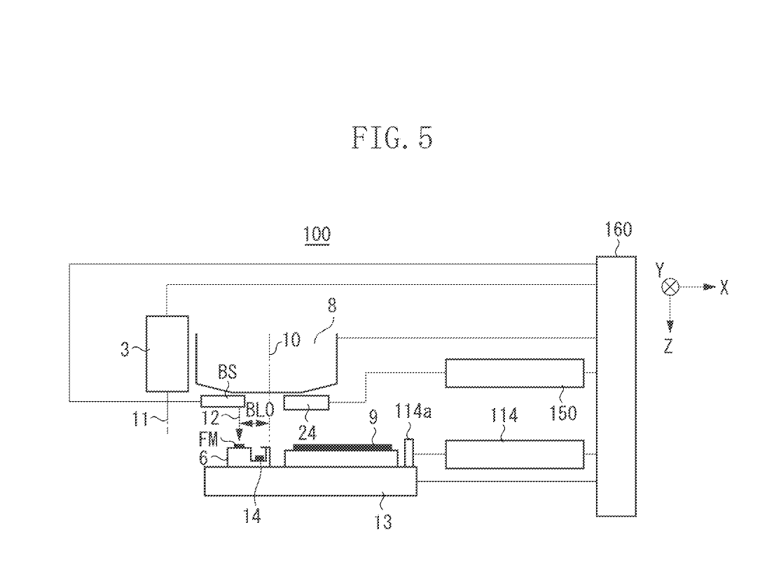

Subsequently, in step S2, the position (L2) of the optical axis 12 of the second measurement unit BS is measured. FIG. 5 illustrates the state of measuring the position of the reference mark FM by the second measurement unit BS while the stage 13 is moved. The position of the base line BL0 can be obtained by obtaining the difference (displacement vector) between the position of the optical axis 12 obtained in this step and the position of the optical axis 10 of the electron optical system obtained in step S1.

Note that the distance (displacement vector) L0 between the reference position of the knife edge included in the electron beam detector 14 and the reference position of the reference mark FM is measured in advance by an external measuring instrument or the like. The position of the optical axis 10 and the position of the optical axis 12 are measured by the position measuring instrument 114 as the position L1 and the position L2 of the stage 13, respectively and stored in a memory of the control unit 160 or the like. Thus, the distance BL0 can be obtained from the following Formula (1):

BL0=L0+(L1−L2) Formula (1)

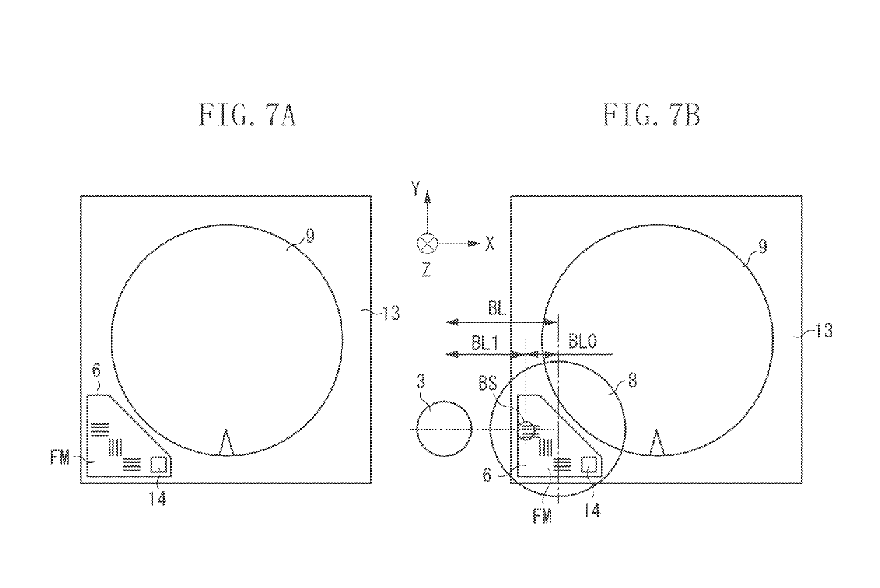

Detailed description is hereinafter made of the measurement of the position of the reference mark FM by the second measurement unit BS. FIGS. 7A and 7B are top views each illustrating a structure example of a stage (reference mark) according to the first exemplary embodiment. In FIGS. 7A and 7B, the same reference symbol as that of the lithography apparatus of FIG. 1 denotes the same component; however, for simplifying the description, the magnitude relation or the arrangement of the components is made slightly different. FIG. 7A illustrates the arrangement of the substrate 9, the stage 13, the reference mark table 6, the reference mark FM, and the electron beam detector 14. Meanwhile, FIG. 7B illustrates the state in which the position of the reference mark FM is determined to be right below the second measurement unit BS, and also illustrates the arrangement of the electron optical system 8 and the first measurement unit 3.

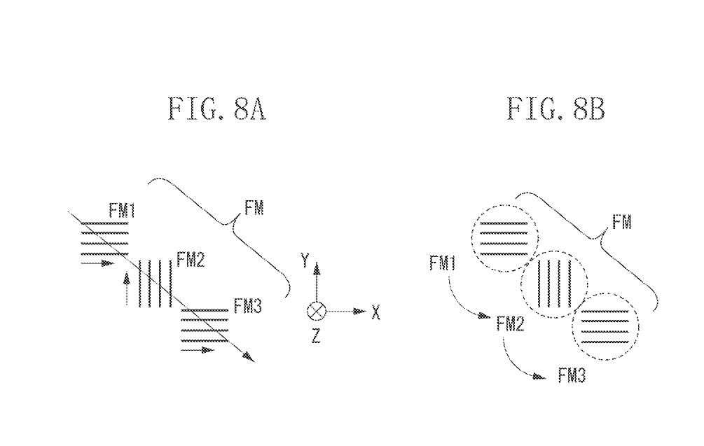

FIGS. 8A and 8B are diagrams illustrating an outline of a measurement of the reference mark. FIG. 8A illustrates the movement of the reference mark FM (stage 13) in the direction of an arrow relative to the measurement light of the second measurement unit BS. Here, the reference mark FM includes FM1, FM2, and FM3, each of which includes one or a plurality of mark elements (in FIGS. 8A and 8B, each mark includes four mark elements (bars) arranged periodically in one direction). FM1, FM2, and FM3 are disposed side by side in a direction at an angle of 45° clockwise relative to the X axis. When the marks are arranged so that the moving direction and the longitudinal (major-axis) direction of the mark element do not cross one another and are not in parallel as illustrated in FIG. 8A, the positions in the X-direction and the Y-direction can be measured at one time by the movement (scanning) in one direction.

On the other hand, FIG. 8B illustrates a state of the measurement of the position of the reference mark FM by the first measurement unit 3. Circles drawn with a dotted line represent the field of view of the optical system of the first measurement unit 3. FIG. 8B illustrates the measurement performed by sequentially capturing the image while the mark elements FM1, FM2, and FM3 are sequentially stopped. The details are made apparent in the description of step S3.

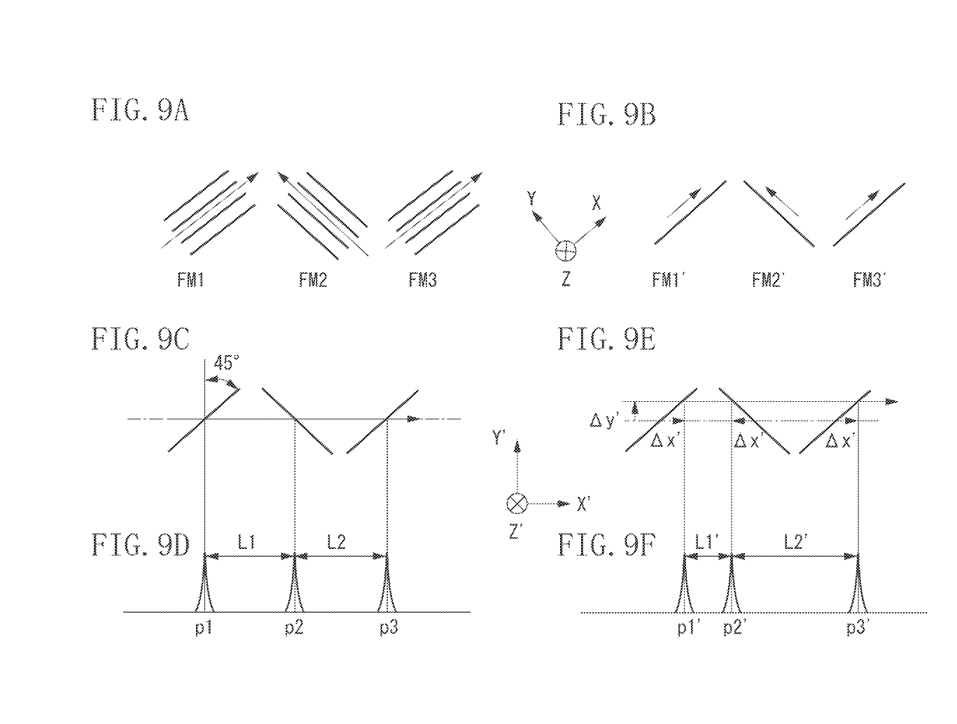

FIGS. 9A to 9F are diagrams illustrating details of the measurement of the reference mark by the second measurement unit BS. With reference to FIGS. 9A to 9F, the measurement by the second measurement unit BS is described. For the convenience of the description, FIG. 9A illustrates the reference mark FM in FIG. 8A that is rotated by 45° counterclockwise. The arrow in FIG. 9A indicates the elongated or longitudinal direction of the mark element. The longitudinal directions of the mark elements FM1 and FM3 are in parallel to a first direction (for example, X-axis direction) and the longitudinal direction of the mark element FM2 is in parallel to a second direction (for example, Y-axis direction) differently from the mark elements FM1 and FM3. For simplifying the description, FIG. 9B illustrates marks in which FM1, FM2, and FM3 each including four mark elements in FIG. 9A are replaced by FM1′, FM2′, and FM3′ each including one mark element (bar). With the use of the marks in FIG. 9B, a coordinate system is defined using the X′ and Y′ in FIGS. 9C to 9F as new coordinate axes (this does not affect the generality), and the measurement of the reference mark FM by the second measurement unit BS is described with reference to FIGS. 9C to 9F.

It is assumed that the stage 13 is moved relative to the reference marks FM in FIG. 9C so that the measurement light of the second measurement unit BS is scanned on the arrow. The measurement signals obtained from the three mark elements in that case are illustrated in FIG. 9D. In FIG. 9D, assuming that the positions of the peaks (or center of gravity of the mountain-like waveform) of the measurement signals are p1, p2, and p3, the positions of the reference mark FM in the X′ direction and the Y′ direction are obtained by the following Formula (2) and Formula (3):

x′={(p2+p1)/2+(p3+p2)/2}/2 Formula (2)

y′=−{(p2−p1)−(p3−p2)}/4 Formula (3)

p2−p1=p3−p2=0 Formula (4)

As long as the relation satisfies Formula (4), the scanning position in the Y′ direction in FIG. 9C can be set as the original point Y′₀ in the Y′ direction.

Next, if the scanning position is displaced by Δy′ in the Y′ direction as illustrated in FIG. 9E, the positions of the peaks of the measurement signal are as illustrated in FIG. 9F. Assuming that the positions of the peaks are p1′, p2′, and p3′, the position of the reference mark FM in the X′ direction and the Y′ direction is obtained by the following formulae:

$$\begin{matrix}\begin{matrix}{x}^{′} = \{ ( p {2}^{′} + p {1}^{′} ) / 2 + ( p {3}^{′} + p {2}^{′} ) / 2 \} / 2 \\ = \{ ( p 2 - Δ {x}^{′} + p 1 + Δ {x}^{′} ) / 2 + \\ ( p 3 + Δ {x}^{′} + p 2 - Δ {x}^{′} ) / 2 \} / 2 \\ = \{ ( p 2 + p 1 ) / 2 + ( p 3 + p 2 ) / 2 \} / 2\end{matrix} & Formula ( 5 ) \\ \begin{matrix}{y}^{′} = - \{ ( p {2}^{′} - p {1}^{′} ) - ( p {3}^{′} - p {2}^{′} ) \} / 4 \\ = - [ \{ ( p 2 - Δ {x}^{′} ) - ( p 1 + Δ {x}^{′} ) \} - \\ \{ ( p 3 + Δ {x}^{′} ) - ( p 2 - Δ {x}^{′} ) \} ] / 4 \\ = Δ {x}^{′} \\ = Δ {y}^{′}\end{matrix} & Formula ( 6 )\end{matrix}$$

Since the tilt angle θ of the mark element (bar) is 45°, the relation between the peak positions p1, p2, and p3 and the peak positions p1′, p2′, and p3′ before and after the displacement of the scanning position in the Y′ direction by Δy′ is as follows:

p1′=p1+Δx′ Formula (7)

p2′=p2−Δx′ Formula (8)

p3′=p3+Δx′ Formula (9)

Δx′=Δy′ Formula (10)

If the tilt angle θ is not 45°, Formula (10) may be replaced by Formula (11):

Δx′=Δy′×tan θ Formula (11)

Formula (2) and Formula (5) indicate that even though the scanning position is displaced by Δy′ in the Y′ direction as illustrated in FIG. 9E, the measurement value of the position in the X′ direction is not influenced (remains the same). Thus, the position in the X′ direction obtained by Formula (2) can be defined as the original point X′₀ in the X′ direction.

Note that the reference mark of FIG. 9B is obtained by simplifying the reference mark of FIG. 9A and any reference mark is actually applicable. The reference mark FM in FIG. 9B is formed by arranging FM1′, FM2′, and FM3′ each including one mark element (one bar). In a manner similar to the case of FIG. 9A, as for the longitudinal directions of FM1′, FM2′ and FM3′, the longitudinal directions of FM1′ and FM3′ are the same as each other, and are different from that of FM2′.

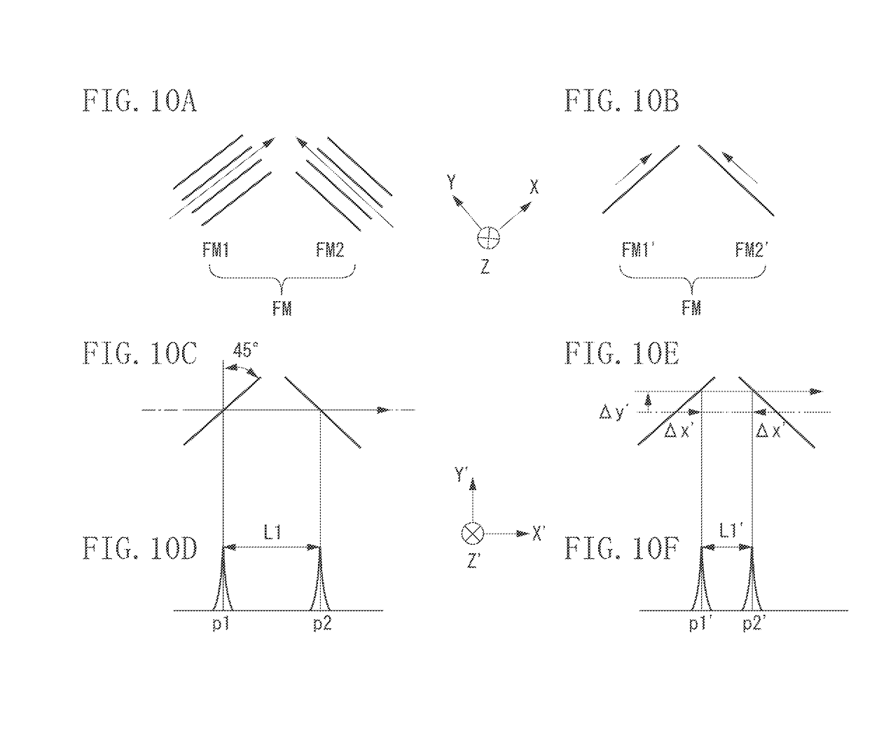

FIGS. 10A to 10F are diagrams illustrating comparative examples of the measurement of the reference mark. The reference mark FM illustrated in FIGS. 10A and 10B is not suitable as the reference mark if, for example, the stage 13 is rotated slightly around the Z-axis for some reason, because the measurement error occurs. FIGS. 10C to 10F are related to the measurement conducted while scanning the stage 13 relative to the reference mark FM of FIG. 10B. FIGS. 10C to 10F correspond to FIGS. 9C to 9F, respectively.

In the measurement of the scanning position illustrated in FIG. 10C, the signal having two peaks as illustrated in FIG. 10D is detected. The position of the reference mark FM in the X′ direction and the Y′ direction based on the peak positions p1 and p2 is obtained from Formula (12) and Formula (13):

x′=(p2+p1)/2 Formula (12)

y′=−(p2−p1)/2 Formula (13)

The position of x′ represented by Formula (12) is the position of the middle point between p1 and p2, and remains to be the same even though the scanning position on the mark has displaced in the Y′ direction. Therefore, the position of this middle point can be defined as the original point X′₀ in the X′ direction.

Here, assuming that the scanning position in the Y′ direction in FIG. 10C is the original point position in the Y′ direction, Formula (14) holds:

Y′₀=−(p2−p1)/2 Formula (14)

and the y′-coordinate of the reference mark FM can be obtained by the following formula:

y′=−(p2−p1)/2−Y′₀ Formula (15)

Next, the position of the reference mark FM in the occurrence of the displacement of the scanning position in the Y′ direction from the original point position in the Y′ direction by Δy′ as illustrated in FIG. 10E is obtained by the following formulae:

$$\begin{matrix}\begin{matrix}{x}^{′} = ( p {2}^{′} + p {1}^{′} ) / 2 \\ = \{ ( p 2 - Δ x ) + ( p 1 + Δ x ) \} / 2 \\ = ( p 2 + p 1 ) / 2\end{matrix} & Formula ( 16 ) \\ \begin{matrix}{y}^{′} = ( p {2}^{′} - p {1}^{′} ) / 2 - {Y}_{0}^{′} \\ = - \{ ( p 2 - Δ {x}^{′} ) - ( p 1 + Δ {x}^{′} ) \} / 2 - {Y}_{0}^{′} \\ = Δ {x}^{′}\end{matrix} & Formula ( 17 )\end{matrix}$$

Here, since the tilt angle of the mark element in the longitudinal direction relative to the scanning direction is 45° counterclockwise, the change in the peak position of the measurement signal in the occurrence of the displacement of the scanning position in the Y′ direction by Δy′ satisfies Δx′=Δy′ in a manner similar to Formula (10). If the stage 13 is slightly rotated, however, the original point position in the X′ direction represented by Formula (12) and the original point position in the Y′ direction represented by Formula (14) may change. On the other hand, three mark elements (group) (FM1′-3′ or FM1-3) are suitable as the structure of the reference mark because the position of the original point P₀(X′₀, Y′₀) can be specified by conducting the measurement based on the scanning position that satisfies the relation of Formula (4).

### <Step S3: Measurement of Position of Optical Axis of First Measurement Unit 3>

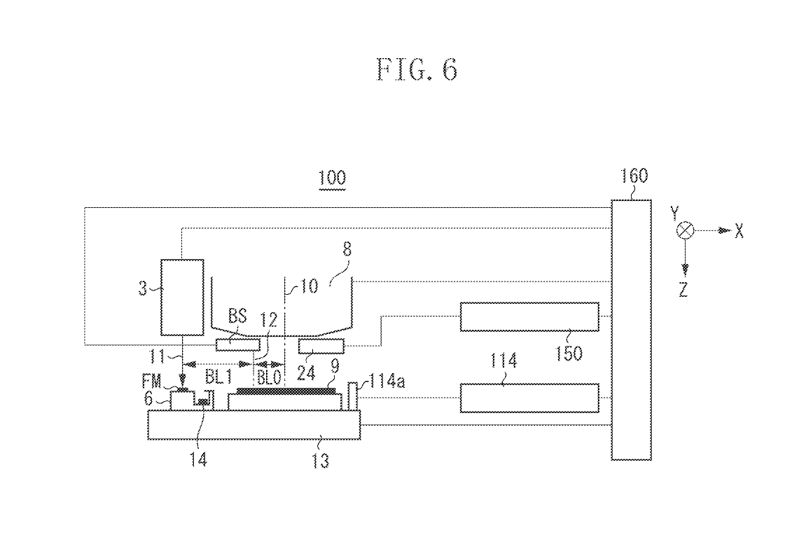

Subsequently, the process of step S3 in FIG. 2 is described. FIG. 6 illustrates a state of measuring the position of the reference mark FM by the first measurement unit 3. Based on the image information of the reference mark FM acquired via the optical system of the first measurement unit 3, the control unit 160 obtains the measurement value of the position of the reference mark FM. The control unit 160 stores the position L3 of the stage 13 as the measurement value in the memory, for example.

FIG. 8B illustrates a field of view of the optical system of the first measurement unit 3 relative to the reference mark FM (FM1, FM2, and FM3) also used in step S2 in the form of dotted circles, and also illustrates a flow of sequentially measuring the positions of the reference mark FM (FM1, FM2, and FM3). The control unit 160 can obtain the position (L3) of the optical axis of the first measurement unit 3 as the average value of the positions of FM1, FM2, and FM3 constituting the reference mark FM (the corresponding positions of the stage 13). In this manner, the reference mark FM can be used in the measurement of both the second measurement unit BS and the first measurement unit 3.

Based on the measurement values obtained in step S1 to step S3, the base line of the first measurement unit 3 can be obtained by the following formula:

BL=BL0+BL1 Formula (18)

Here, the BL1 corresponds to the distance (displacement vector) between the position L2 of the optical axis 10 of the second measurement unit BS measured in step S2 and the position L3 of the optical axis 11 of the first measurement unit 3 measured in step S3 as represented by Formula (19).

BL1=L2−L3 Formula (19)

As described above, the measurement of the position of the optical axis of the electron optical system 8 by the electron beam detector 14 or 24 is less frequently performed than the measurement of the position of the optical axis by the first measurement unit 3 and the measurement of the position of the optical axis by the second measurement unit BS. This enables to measure the base line BL of the first measurement unit 3 with high accuracy and in a short time. The reason is as follows. The distance BL0 between the optical axis 12 of the second measurement unit BS and the optical axis 10 of the electron optical system is set (designed) to be much shorter than the distance BL between the optical axis 11 of the first measurement unit 3 and the optical axis 10 of the electron optical system. If the value of the BL0 is small, the error of the position measurement that is caused due to the movement of the stage 13 moving along the distance can be reduced. Furthermore, if the value of the BL0 is small, the variation due to the disturbance such as heat can be made small accordingly. As a result, the variation in the value of BL0 can be ignored at least for a short period of time. Therefore, by the position measurement of the optical axis 11 by the first measurement unit 3 and the optical axis 12 by the second measurement unit BS, the measurement of the base line of the first measurement unit 3 can be performed quickly and highly accurately.

On the other hand, to make the BL0 sufficiently smaller than BL or BL1, the second measurement unit BS needs to be reduced in size. This can be achieved when, for example, the second measurement unit BS has the limited function of measuring the position of the reference mark FM only. The reference mark FM is, for example, obtained by patterning chromium on a quartz glass plate in a manner similar to a mask or a reticle in optical lithography. In this case, the contrast of the optical image of the reference mark FM becomes excellent (for example, 80% or more) and the robustness of the measurement as required for the first measurement unit 3 that measures the position of the mark formed on the substrate (for example, semiconductor wafer) is not necessary. As for the optical performance, even though the wave aberration of the entire optical system is approximately λ/2, the measurement error is constant just for measuring the reference mark FM with a certain structure, so that the correction for that is easy. Thus, the second measurement unit BS can be reduced in size and can have at least a part thereof including an object optical element disposed below the case (mirror barrel) of the electron optical system 8 as illustrated in FIG. 1. In other words, the BL0 can be made small sufficiently as described above.

On the other hand, the first measurement unit 3 cannot be reduced in size like the second measurement unit BS. This is because the first measurement unit 3 is configured to be able to measure under various optical conditions so that the position of the alignment mark formed on a substrate (semiconductor wafer or the like) subjected to various processes can be measured with high accuracy. More specifically, for example, the first measurement unit 3 has functions of selecting or setting the wavelength of irradiation light, the coherence factor (o), bright field or dark field, necessity of detection of phase difference, etc. By setting the measurement condition suitable for the substrate (alignment mark) of the measurement target utilizing the above functions, the robustness of the measurement can be increased and thus the necessary overlapping accuracy or productivity can be achieved. The first measurement unit 3 is required to have high optical performance, for example, the wave aberration of the entire optical system needs to be λ/10 or less. Thus, the first measurement unit 3 is required to have the function of setting various measurement conditions and have high optical performance and therefore it is difficult to reduce the size of the first measurement unit 3. As a result, the base line cannot be made small like the base line of the second measurement unit BS.

The structure of the reference mark FM in the present exemplary embodiment is as follows. The reference mark FM may include a first mark element extending in a first direction (for example, X direction), and a second mark element extending in a second direction (for example, Y direction) different from the first direction. The reference mark FM may include a first mark element group in which a plurality of first mark elements extending in the first direction is arranged in the second direction, and a second mark element group in which a plurality of second mark elements extending in the second direction is arranged in the first direction. The reference mark FM may include a plurality of at least one of the first mark element groups and the second mark element groups. The reference mark FM may include a plurality of one of the first mark elements extending in the first direction and the second mark elements extending in the second direction different from the first direction.

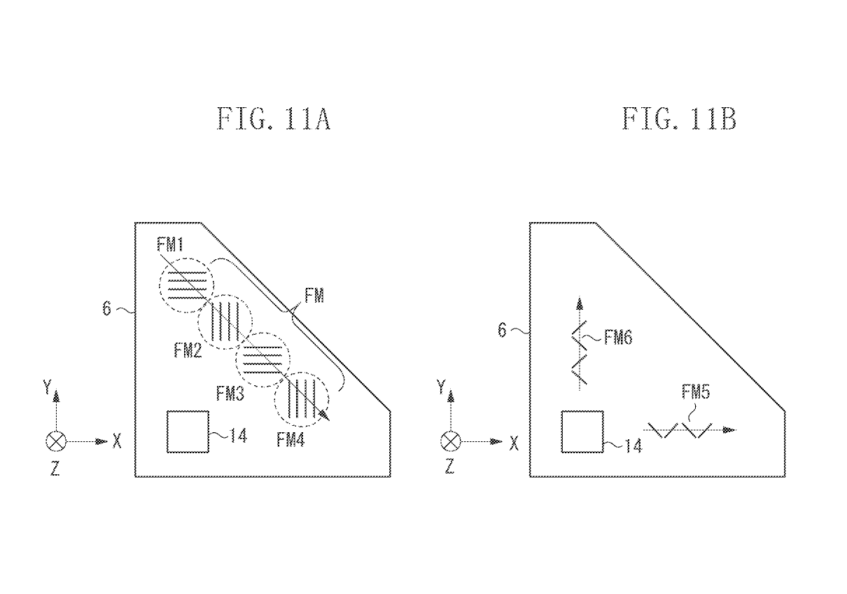

FIGS. 11A and 11B are top views each illustrating a structure example of the stage (reference mark) according to a second exemplary embodiment. In FIG. 11A, the mark element groups FM1 to FM4 each including a plurality of mark elements (four bars) are arranged as the reference mark FM. In FIG. 11A, the reference mark FM is configured to be measured by both the first measurement unit 3 and the second measurement unit BS.

The position in the two directions of X-axis direction and Y-axis direction can be measured in a manner similar to the first exemplary embodiment by scanning the reference mark FM relative to the second measurement unit BS once in a direction of 45° relative to the X axis (or Y axis). Due to the averaging effect obtained by increasing the number of mark element groups FMi, the measurement accuracy is improved. On the other hand, in FIG. 11A, the circles drawn with the dotted line indicate the field of view of the optical system of the first measurement unit 3. In the case of measuring the position of the reference mark FM by the first measurement unit 3, the position of the reference mark FM in the X direction is measured by measuring the position of each of the two mark element groups of FM2 and FM4. Similarly, the position of the reference mark FM in the Y direction is measured by measuring the position of each of the two mark element groups of FM1 and FM3. In the structure of the first exemplary embodiment, the number of the mark element groups for the X-directional position measurement is one, and the number thereof for the Y-directional position measurement is two. Thus, the measurement accuracy by the averaging effect is not uniform. In the structure of the second exemplary embodiment, however, the number of the mark element groups for the X-directional position measurement and the Y-directional position measurement is the same. Thus, the measurement accuracy by the averaging effect is uniform regardless of the direction.

Note that as each mark element group FMi, four bars are arranged periodically in the X direction or Y direction in the above example, however, the number of bars is not limited to four and may be increased or decreased depending on the required overlapping accuracy. The number of the mark element groups FMi is two for the X-directional position measurement and two for the Y-directional position measurement in the second exemplary embodiment, however, the present invention is not limited thereto and the number may be increased or decreased depending on the required overlapping accuracy. If the required overlapping accuracy is different depending on the measurement direction, at least one of the number of mark elements (for example, bars) in the mark element group FMi and the number of mark element groups FMi may be made different depending on the measurement direction according to the accuracy of each measurement direction.

FIG. 11B illustrates another structure example of the reference mark FM, in which two reference marks FM in FIG. 10B are arranged in the scanning direction. In the example in FIG. 11B, the reference mark FM5 and the reference mark FM6 are provided for the reference mark table 6. At least one of the reference marks FM5 and FM6 is selected and scanned relative to the second measurement unit BS. Thus, the measurement in the X direction and the Y direction can be conducted by one scanning. If the reference mark FM5 is selected, scanning may be performed once in the X direction. If the reference mark FM6 is selected, scanning may be performed once in the Y direction. On the other hand, the measurement of the position of the reference mark by the first measurement unit may include, for example, the measurement of the position in the X direction based on the image information obtained via the capture of the image of the reference mark FM5 and the measurement of the position in the Y direction based on the image information obtained via the capture of the image of the reference mark FM6.

Note that the structure of the reference mark FM in the present exemplary embodiment is as follows. The reference mark FM may include a plurality of first mark elements extending in the first direction and a plurality of second mark elements extending in the second direction different from the first direction.

A method for manufacturing an article according to an exemplary embodiment of the present invention is suitable for manufacturing a microdevice such as a semiconductor device or an article such as an element having a microscopic structure. The method for manufacturing an article according to the present exemplary embodiment includes a step of forming a latent image pattern using a lithography apparatus in a photosensitizer applied on a substrate (step of forming a pattern on a substrate), and a step of developing the substrate provided with the latent image pattern in the previous step (step of developing the substrate having the pattern). This manufacturing method may include other known steps (oxidizing, forming film, depositing, doping, planarizing, etching, removing resist, dicing, bonding, packaging, etc.). The method for manufacturing an article according to the present exemplary embodiment is advantageous in terms of at least one point of the performance, quality, productivity, and production cost as compared with a conventional method.

The exemplary embodiments of the present invention have been described so far, however, the present invention is not limited thereto and may be modified or changed variously without departing the scope thereof. For example, the lithography apparatus 100 may be a lithography apparatus that forms a pattern on a substrate with a plurality of electron beams (charged particle beams). In this case, the position of the optical axis 10 (axis) of the electron optical system 8 in step S1 can be measured using the electron beam closest to the optical axis 12 of the second measurement unit BS among the plurality of electron beams delivered to the substrate 9 via the electron optical system 8. This moves the stage 13 less when the base line of the second measurement unit BS is measured; thus, this method is advantageous because the measurement takes less time. The lithography apparatus 100 may have a plurality of sets (groups) each including the first measurement unit 3, the second measurement unit BS, and the reference mark FM. The lithography apparatus 100 as above is advantageous in at least one of the quick measurement of the position of the alignment mark on the substrate and the measurement of the position of the alignment mark at the timing close to or in parallel to the pattern formation (drawing). In the case of such a structure, the measurement of the base lines of the plurality of second measurement units BS can be conducted using the electron beam closest to that optical axis.

According to the exemplary embodiment the present invention, for example, the lithography apparatus advantageous in measurement of the base line can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-096009, filed Apr. 30, 2013, which is hereby incorporated by reference herein in its entirety.

What is claimed is:

1. A lithography apparatus configured to form a pattern on a substrate with a charged particle beam, the apparatus comprising:
a stage having a reference mark and configured to hold the substrate and be moveable;
an optical system configured to irradiate the substrate with the charged particle beam;
a first measurement device having an optical axis apart from an axis of the optical system by a first distance, and configured to measure a position of an alignment mark formed on the substrate;
a second measurement device having an optical axis apart from the axis of the optical system by a second distance shorter than the first distance, and configured to measure a position of the reference mark; and
a processor configured to obtain a base line of the first measurement device based on positions of the reference mark respectively measured by the first measurement device and the second measurement device and a base line of the second measurement device,
wherein the position of the reference mark is measured by the second measurement device based on an optical signal obtained via the reference mark with the stage moved.

2. The apparatus according to claim 1,
wherein the reference mark includes a first mark element having a longitudinal thereof in a first direction and a second mark element having a longitudinal thereof in a second direction, and
wherein the position of the reference mark is measured by the second measurement unit based on an optical signal obtained via the first mark element and the second mark element with the stage moved.

3. The apparatus according to claim 1, further comprising a third measurement device configured to measure the position of the reference mark by detecting a charged particle coming from the reference mark onto which the charged particle beam has been incident,
wherein the processor is configured to obtain the base line of the second measurement device based on positions of the reference mark respectively measured by the second measurement device and the third measurement device.

4. The apparatus according to claim 1, further comprising
a housing configured to house the optical system,
wherein the second measurement device includes an object optical element and a detector configured to detect light from the reference mark via the object optical element, the object optical element being disposed on or under a bottom of the housing.

5. The apparatus according to claim 3,
wherein the lithography apparatus is configured to form the pattern on the substrate with a plurality of charged particle beams,
wherein the third measurement device is configured to measure the position of the reference mark using a charged particle beam closest to the optical axis of the second measurement device among the plurality of charged particle beams.

6. The apparatus according to claim 2,
wherein the reference mark includes a first mark element group in which a plurality of the first mark element is arranged in the second direction, and a second mark element group in which a plurality of the second mark element is arranged in the first direction.

7. The apparatus according to claim 6,
wherein the reference mark includes a plurality of at least one of the first mark element group and the second mark element group.

8. The apparatus according to claim 2,
wherein the reference mark includes a plurality of at least one of the first mark element and the second mark element.

9. The apparatus according to claim 2,
wherein the position of the reference mark is measured by the first measurement device by capturing images of the first mark element and the second mark element in sequence.

10. The apparatus according to claim 1,
wherein the apparatus comprises a plurality of sets each including the first measurement device, the second measurement device and the reference mark.

11. A method of manufacturing an article, the method comprising steps of:
forming a pattern on a substrate using a lithography apparatus;
developing the substrate on which the pattern has been formed; and
processing the developed substrate to manufacture the article,
wherein the lithography apparatus forms the pattern on the substrate with a charged particle beam, and includes:
a stage having a reference mark and configured to hold the substrate and be moveable;
a charged particle optical system configured to irradiate the substrate with the charged particle beam;
a first measurement device having an optical axis apart from an axis of the charged particle optical system by a first distance, and configured to measure a position of an alignment mark formed on the substrate;
a second measurement device having an optical axis apart from the axis of the charged particle optical system by a second distance shorter than the first distance, and configured to measure a position of the reference mark; and
a processor configured to obtain a base line of the first measurement device based on positions of the reference mark respectively measured by the first measurement device and the second measurement device and a base line of the second measurement device,
wherein the position of the reference mark is measured by the second measurement device based on an optical signal obtained via the reference mark with the stage moved.
